(19) United States
(12) Patent Application Publication
(10) Pub. No.: US 2013/0215586 A1
(43) Pub. Date: Aug. 22, 2013

(54) WIRING SUBSTRATE

(71) Applicant: IBIDEN Co., Ltd., (US)

(72) Inventors: Takeshi Furusawa, Ogaki-shi (JP); Shinobu Kato, Ogaki-shi (JP); Toshiki Furutani, Ogaki-shi (JP)

(73) Assignee: IBIDEN CO., LTD., Ogaki-shi (JP)

(21) Appl. No.: 13/690,689

(22) Filed: Nov. 30, 2012

Related U.S. Application Data
(60) Provisional application No. 61/599,637, filed on Feb. 16, 2012.

(51) Int. Cl. H05K 1/18

(52) U.S. Cl. CPC H05K 1/184
USPC 361/767

(57) ABSTRACT

A wiring substrate includes a motherboard including insulation layers, conductive layers and interlayer connection conductors, a packaging substrate mounted to the motherboard and having through-hole conductors, pads positioned to mount a semiconductor, uppermost via conductors connecting the through-hole conductors and the pads for the semiconductor, pads positioned to connect a motherboard and lowermost via conductors connecting the through-hole conductors and the pads for the motherboard, and bonding members interposed between the motherboard and packaging substrate and connecting the pads for the motherboard and an outermost conductive layer of the motherboard facing the packaging substrate. The pads for the motherboard, lowermost via conductors, through-hole conductors, uppermost via conductors, bonding members and interlayer connection conductors include a pad, a lowermost via conductor, a through-hole conductor, a bonding member and a stacked interlayer connection conductor structure which are positioned to align in a straight line.

### CROSS-REFERENCE TO RELATED APPLICATIONS

The present application is based upon and claims the benefit of priority from U.S. Application No. 61/599,637, filed Feb. 16, 2012, the entire contents of which are incorporated herein by reference.

### BACKGROUND OF THE INVENTION

1. Field of the Invention

The present invention relates to a wiring substrate formed with a packaging substrate, a motherboard and a bonding member to connect them.

2. Description of Background Art

Japanese Laid-Open Patent Publication No. 2010-283056 describes packaging, and according to Japanese Laid-Open Patent Publication No. 2010-283056, a semiconductor element is mounted on one surface of the package, and the other surface is connected to a motherboard through external connection terminals such as solder balls. The entire contents of this publication are incorporated herein by reference.

### SUMMARY OF THE INVENTION

According to one aspect of the present invention, a wiring substrate includes a motherboard having resin insulation layers, conductive layers and interlayer connection conductors connecting the conductive layers through the resin insulation layers, a packaging substrate mounted to the motherboard and having a core substrate including a resin substrate, through-hole conductors penetrating through the resin substrate, an uppermost interlayer resin insulation layer formed on a first surface of the resin substrate, pads formed on the first interlayer resin insulation layer and positioned to mount a semiconductor device, uppermost via conductors connecting the through-hole conductors and the pads for the semiconductor device through the uppermost interlayer resin insulation layer, a lowermost interlayer resin insulation layer formed on a second surface of the resin substrate, pads formed on the lowermost interlayer resin insulation layer and positioned to connect a motherboard, and lowermost via conductors connecting the through-hole conductors and the pads for the motherboard through the lowermost interlayer resin insulation layer, and bonding structures interposed between the motherboard and the packaging substrate and connecting the pads for the motherboard in the packaging substrate and an outermost conductive layer of the conductive layers in the motherboard facing the packaging substrate. The pads for the motherboard, the lowermost via conductors, the through-hole conductors, the uppermost via conductors, the bonding structures and the interlayer connection conductors include a pad, a lowermost via conductor, a through-hole conductor, a bonding structure and a stacked interlayer connection conductor structure which are positioned to align in a straight line.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring substrate according to a first embodiment of the present invention;

FIG. 2 is a cross-sectional view of a motherboard according to the first embodiment;

FIGS. 3(A)-3(H) are views showing steps for manufacturing a motherboard according to the first embodiment;

FIGS. 4(A)-4(E) are views showing steps for manufacturing a motherboard according to the first embodiment;

FIGS. 5(A)-5(C) are views showing steps for manufacturing a motherboard according to the first embodiment;

FIG. 6 is a cross-sectional view of a packaging substrate according to the first embodiment;

FIGS. 7(A)-7(E) are views showing steps for manufacturing a packaging substrate according to the first embodiment;

FIGS. 8(A)-8(D) are views showing steps for manufacturing a packaging substrate according to the first embodiment;

FIGS. 9(A)-9(C) are views showing steps for manufacturing a packaging substrate according to the first embodiment;

FIGS. 10(A)-10(C) are views showing steps for manufacturing a packaging substrate according to the first embodiment;

FIG. 11 is a cross-sectional view of a wiring substrate according to a second embodiment;

FIG. 12 is a plan view of a packaging substrate according to a third embodiment;

FIGS. 13(A)-13(B) are views illustrating a bottom diameter, top diameter and land diameter of a via conductor;

FIGS. 14(A)-14(B) are views illustrating the land of a via conductor;

FIG. 15(A): a view illustrating an example in which the bottoms of adjacent via conductors face each other by sandwiching a conductive circuit; FIG. 15(B): a view illustrating an example in which one bottom is projected on the other bottom;

FIG. 16 is a view illustrating a through-hole land of a through-hole conductor and the region directly on the through-hole conductor;

FIG. 17 is a cross-sectional view of a wiring substrate according to a modified example of the first embodiment;

FIGS. 18(A)-18(B) are views illustrating positions of a through-hole conductor and a via conductor; and

FIG. 19 is a cross-sectional view of a motherboard according to another modified example of the first embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

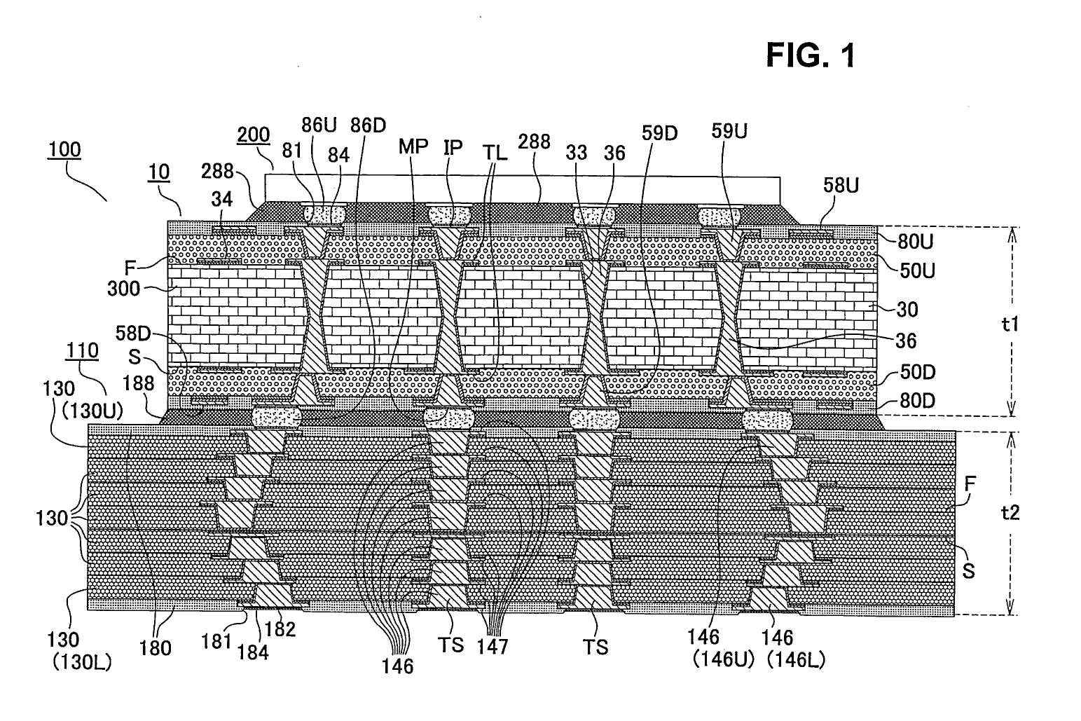

Wiring substrate 100 according to a first embodiment is described with reference to FIGS. 1-10. FIG. 1 shows wiring substrate 100 which is formed with motherboard (first substrate) 110, packaging substrate (second substrate) 10 and bonding members (86D) for connection with the motherboard and the packaging substrate. Then, semiconductor element 200 is mounted on the packaging substrate of the wiring substrate. Resin filler 188 is filled between motherboard 110 and packaging substrate 10. Resin filler 188 is not always required. Underfill 288 is filled between packaging substrate 10 and semiconductor element 200.

Thickness (t2) of motherboard 110 is greater than thickness (t1) of packaging substrate 10. Thickness (t1) is set from 0.1 mm to 0.35 mm, and (t2) is set from 0.4 mm to 1.2 mm. When (t1) and (t2) satisfy the above relationship, heat tends to be transferred from the packaging substrate to the motherboard.

### Motherboard (First Substrate)

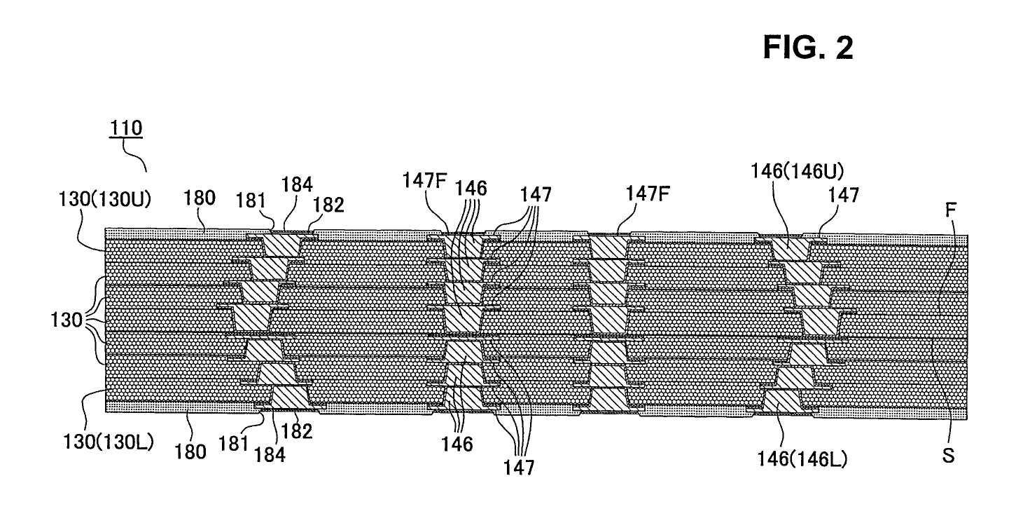

FIG. 2 shows a cross-sectional view of motherboard 110. The motherboard has multiple resin insulation layers 130 and multiple conductive layers 147. Furthermore, the motherboard has interlayer connection conductors (via conductors) 146 made by filling plating in openings for interlayer connection conductors (via-conductor openings) that penetrate through their respective resin insulation layers. Resin insulation layers 130 and conductive layers 147 are alternately laminated, and different conductive layers are connected by interlayer connection conductors (via conductors). In FIG. 2, the number of resin insulation layers is 7, and the number of conductive layers is 8. As shown in FIG. 2, the motherboard has full stacked-via structure (147F). Two full stacked-via structures are shown in FIG. 2. A full stacked-via structure means a structure where via conductors in their respective resin insulation layers, from uppermost via conductor (146U) (a via conductor formed in uppermost resin insulation layer (130U)) to lowermost via conductor (146L) (a via conductor formed in lowermost resin insulation layer (130L)), are laminated along a substantially straight line.

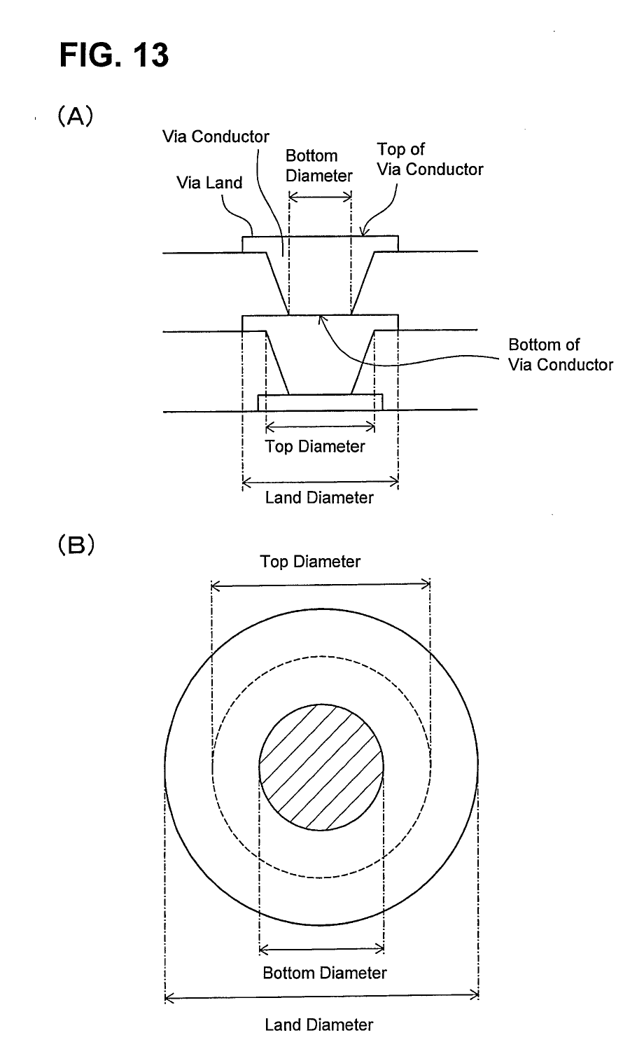

FIGS. 13(A) and (B) show bottom diameters, top diameters and land diameters of via conductors. The upper view is a cross-sectional view, and the lower view is a plan view. The opening for a via conductor becomes narrower from one surface of a resin insulation layer toward the other surface. The diameter of the opening on one surface is the top diameter, and the diameter of the opening on the other surface is the bottom diameter. The top diameter is greater than the bottom diameter. A via land is formed around the via conductor. The via land is a conductive circuit that extends from the via conductor and is formed on the resin insulation layer.

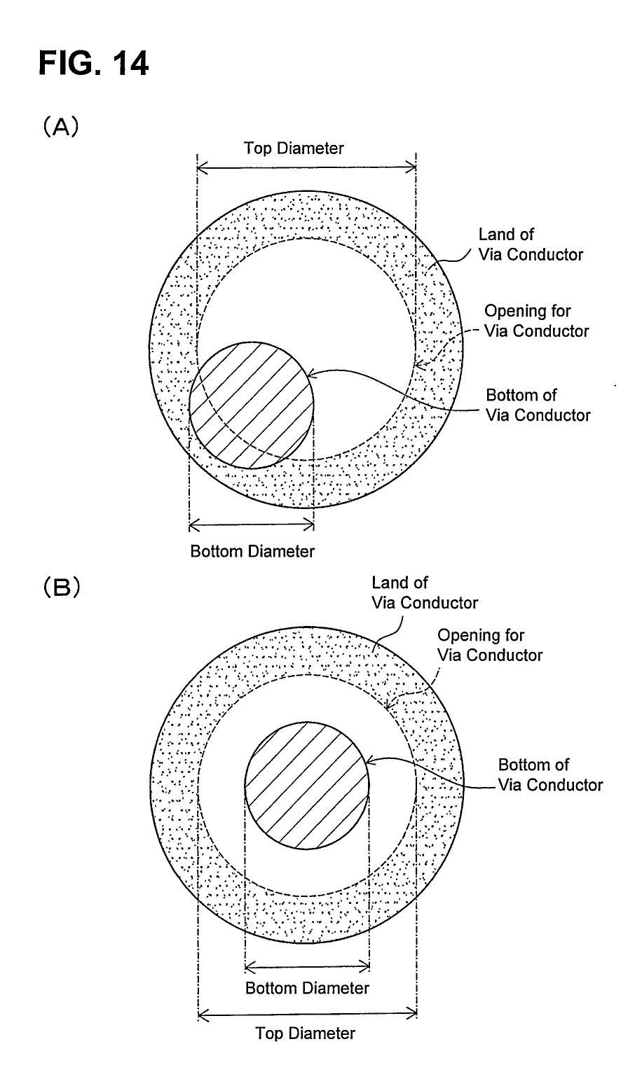

FIG. 13(A) further shows tops and bottoms of via conductors. When the bottom of one via conductor is connected to the top of the other via conductor, the bottom of one via conductor is formed within the land of the other via conductor (FIG. 14(A)). The bottom of one via conductor is preferred to be formed within the other via conductor (FIG. 14(B)). In FIG. 14(B), the bottom of one via conductor is connected to the top of the other via conductor excluding its via land. Namely, the bottom of one via conductor is connected directly on the conductor filled in the opening for the other via conductor.

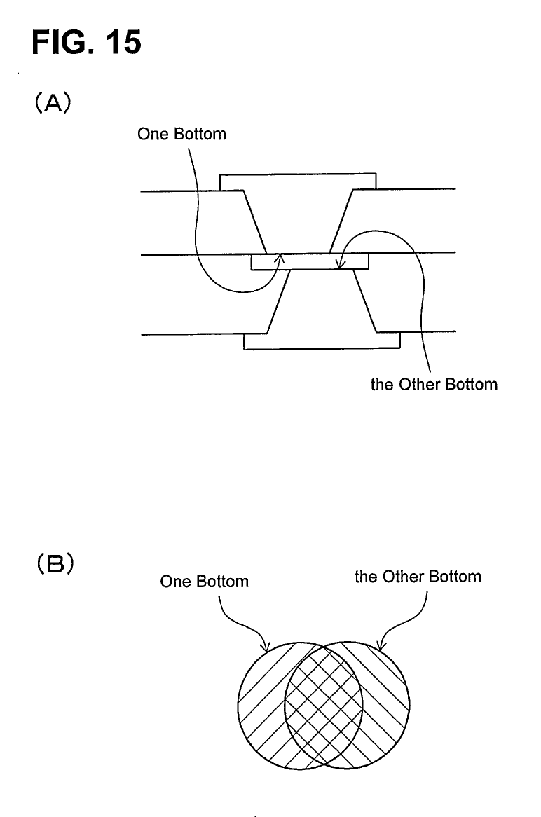

FIG. 15(A) shows an example in which bottoms of adjacent via conductors face each other by sandwiching a conductive circuit. FIG. 15(B) shows an example in which one bottom is projected on the other bottom. In the present embodiment, one bottom and the other bottom overlap as shown in FIG. 15(B). Half or more of the areas of the bottoms are preferred to overlap. When each via conductor of a full stacked-via structure is laminated as above, heat dissipation improves.

Solder-resist layers 180 with openings 181 are formed on uppermost and lowermost resin insulation layers (130U, 130L). Via conductors and conductive circuits exposed through the openings work as external terminals. Nickel layer 182 and gold layer 184 are formed on the external terminals. Bonding members (not shown in the drawings) such as solder bumps are formed on the external terminals, and a packaging substrate, an electronic component and a motherboard are connected through the bonding members. Since the motherboard has a full stacked-via structure, the conductor distance in a thickness direction is reduced, and wiring resistance decreases. Heat dissipation improves. The loss of electric power is suppressed. It is an option for bonding members for connection with a packaging substrate to be formed on the packaging substrate instead of being formed on the motherboard.

### Packaging Substrate (Second Substrate)

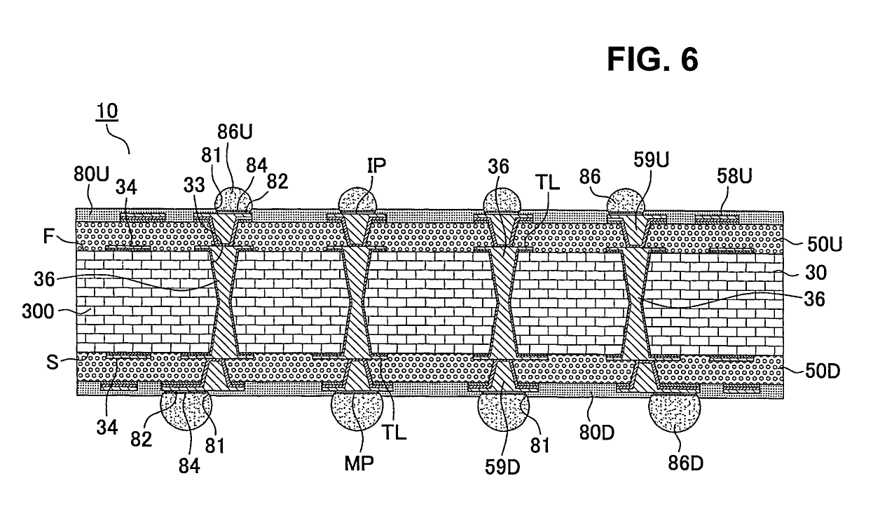

FIG. 6 shows a cross-sectional view of packaging substrate (second substrate) 10. In substantially the center of its thickness direction, packaging substrate 10 has core substrate 30 having first surface (F) and second surface (S). Core substrate 30 has insulative base (resin substrate) 300 which has penetrating holes for through-hole conductors, and through-hole conductors 36 formed by filling plated film in the penetrating holes for through-hole conductors. The through-hole conductors are shaped like an hourglass. The insulative base has first surface (F) and second surface (S), and its thickness is from 60 μm to 200 μm. The diameter of penetrating holes (the greater of the diameters on the first and second surfaces of the insulative base) is from 60 μm to 150 μm, and the minimum diameter (MD) is from 30 μm to 80 μm. The core substrate further includes first conductive layers 34 on first surface (F) and second surface (S) of the insulative base. The first conductive layers include through-hole lands (TL) surrounding through-hole conductors.

Upper buildup layers are formed on first surface (F) of core substrate 30. The upper buildup layers are made up of uppermost interlayer resin insulation layer (50U) formed on the first surface of the core substrate, pads (IP) which are formed on uppermost interlayer resin insulation layer (50U) and are for mounting a semiconductor element, and via conductors (uppermost via conductors) (59U) which penetrate through uppermost interlayer resin insulation layer (50U) and connect the pads for mounting a semiconductor element and the through-hole conductors.

Lower buildup layers are formed on second surface (S) of core substrate 30. The lower buildup layers are made up of lowermost interlayer resin insulation layer (50D) formed on the second surface of the core substrate, pads (MP) which are formed on lowermost interlayer resin insulation layer (50D) and are for connection with a motherboard, and via conductors (lowermost via conductors) (59D) which penetrate through lowermost interlayer resin insulation layer (50D) and connect the pads for connection with a motherboard and the through-hole conductors.

The packaging substrate has a full stacked-via structure the same as in the motherboard. The full stacked-via structure of the packaging substrate is formed with through-hole conductor 36 and via conductors (59U, 59D) sandwiching through-hole conductor 36. Through-hole conductor 36 and via conductors (59U, 59D) sandwiching the through-hole conductor are laminated along a straight line. A through-hole land is formed around the through-hole conductor. A through-hole land is a conductive circuit extending from the through-hole conductor and formed on the insulative base.

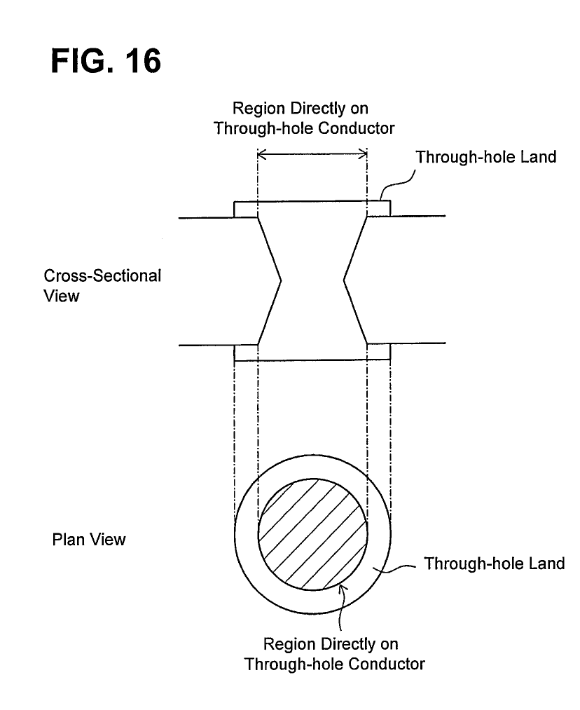

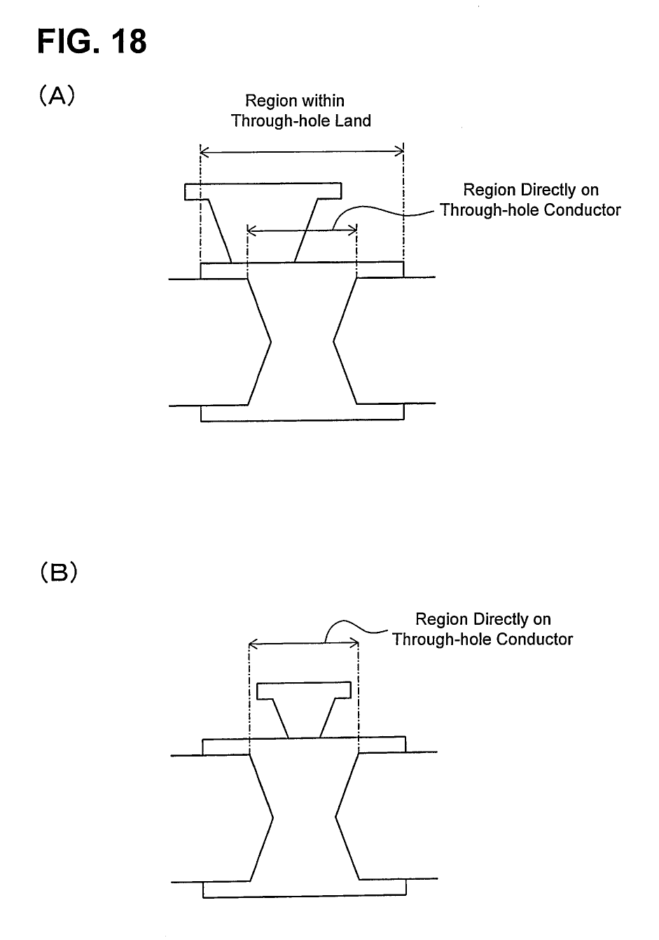

Via conductors in the packaging substrate also have tops and bottoms the same as the via conductors in the motherboard. Also, via-conductor openings have top and bottom diameters (FIG. 13(A)). The region directly on a through-hole conductor and through-hole lands are shown in FIG. 16. The bottom of a via conductor is connected to a through-hole conductor within the through-hole land (FIG. 18(A)). The bottom of the via conductor is preferred to be formed directly on the through-hole conductor (FIG. 18(B)). When each via conductor and a through-hole conductor of full stacked-via structures in the packaging substrate are laminated as above, heat dissipation improves.

Upper solder-resist layer (80U) having openings 81 is formed on the upper buildup layers. The openings of the upper solder-resist layer expose the pads of the upper buildup layers. Lower solder-resist layer (80D) having openings 81 is formed on the lower buildup layers. The openings of the lower solder-resist layer expose the pads of the lower buildup layers. Nickel layer 82 and gold layer 84 are formed on pads (IP, MP). Solder bumps (86U) for mounting a semiconductor element are formed on the pads of the upper buildup layers. It is an option for bonding members (86D) such as solder bumps for connection with a motherboard to be formed on the pads of the lower buildup layers.

When the packaging substrate has a full stacked-via structure, the conductor distance is reduced in a thickness direction, and wiring resistance decreases. Heat dissipation improves. The loss of electric power is suppressed.

The motherboard and the packaging substrate are aligned, and they are bonded by solder bumps. Pads of the packaging substrate for connection with the motherboard and external terminals of the motherboard are connected by solder bumps. As shown in FIG. 1, the wiring substrate has total stacked structure (TS) where a full stacked-via structure in the packaging substrate, a full stacked-via structure in the motherboard and a solder bump are laminated along a straight line.

Heat generated in the semiconductor element is transferred to a full stacked-via structure in the motherboard by way of a full stacked-via structure in the packaging substrate. Since heat is transferred in almost the minimum distance from the upper surface of the packaging substrate to the lower surface of the motherboard, heat generated in the semiconductor element does not build up in the packaging substrate, but is transferred to the motherboard. Heat dissipation improves.

The number of stacked structures that reach from the packaging substrate to the motherboard (total stacked structures) is preferred to be in a predetermined range.

There are multiple pads (MP) (M-pads) for connection with the motherboard. M-pads include multiple first pads. A first pad is part of a total stacked structure. Among the multiple M-pads, 1/5 (20%) to 1/2 (50%) of M-pads (first pads) are part of total stacked structures. For example, when the number of M-pads is 100, full stacked-via structures of the packaging substrate are formed on 20˜50 M-pads, and solder bumps and full stacked-via structures of the motherboard are formed directly under those full stacked-via structures of the packaging substrate. If the percentage of the total stacked structures is less than 20%, heat dissipation is not significantly improved. If the percentage of the total stacked structures exceeds 50%, heat dissipation declines. Without being bound by the theory, the reasons for that are thought to be that since efficiency in wiring design is lowered, the number of buildup layers in the packaging substrate increases, or the size of the packaging substrate enlarges.

The wiring substrate includes signal wiring, power-source wiring and ground wiring. Signal wiring is preferred to have low resistance to allow transmission of high-speed signals. Power-source wiring is preferred to have low resistance to allow instantaneous power supply for the semiconductor element. Therefore, it is not considered preferable to use signal or power-source wiring for heat dissipation, because heat causes an increase in wiring resistance. It is preferable to use ground wiring as the wiring for heat dissipation. Accordingly, a total stacked structure is preferred to be ground wiring. There are multiple ground pads (G-pads) for connection with the motherboard. Among the multiple G-pads, 1/5 (20%) to 1/2 (50%) of G-pads are part of total stacked structures. For example, when the number of G-pads is 100, full stacked-via structures of the packaging substrate are formed on 20-50 G-pads, and solder bumps and full stacked-via structures of the motherboard are formed directly under the full stacked-via structures of the packaging substrate. If the percentage of the total stacked structures is less than 20%, heat dissipation is not significantly improved. If the percentage of the total stacked structures exceeds 50%, heat dissipation declines. Without being bound by the theory, the reasons for that are thought to be that since efficiency in wiring design is lowered, the number of buildup layers in the packaging substrate increases, or the size of the packaging substrate enlarges.

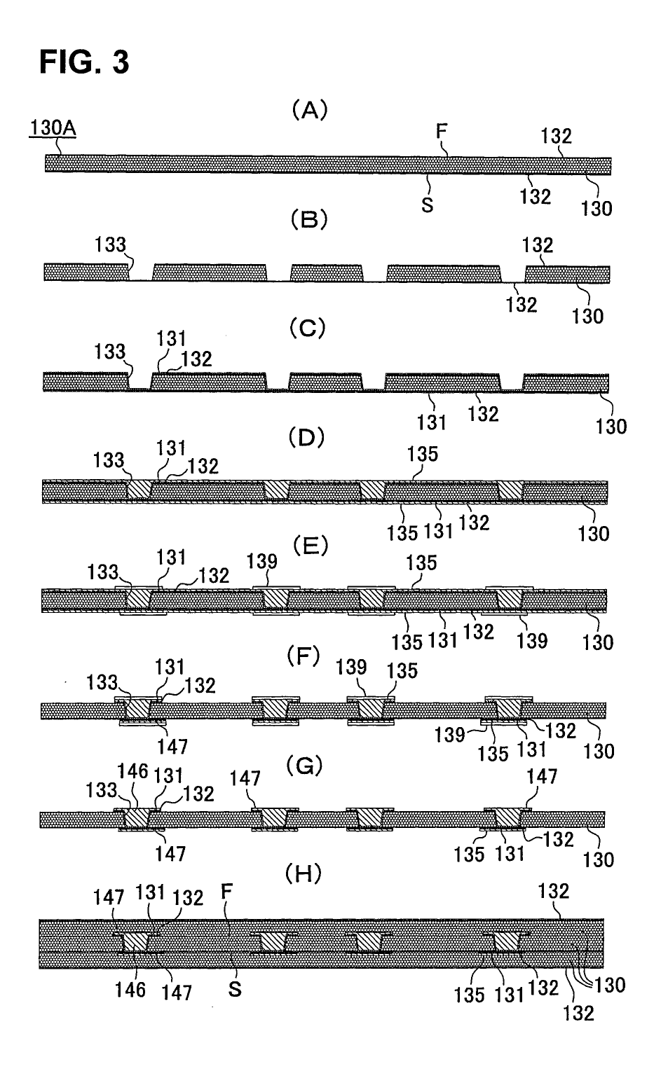

Next, a method for manufacturing motherboard 110 is described with reference to FIGS. 3-5.

(1) Substrate (130A) is prepared, which is made up of resin insulation layer 130 and metal foils (132, 132) laminated on both surfaces of the resin insulation layer (FIG. 3(A)). The resin insulation layer has first surface (F) and a second surface opposite the first surface. The thickness of the resin insulation layer is 40 μm to 150 μm. The resin insulation layer is formed with resin such as epoxy resin and reinforcing material such as glass cloth. As the material for such glass, T-glass (made by Nitto Boseki Co., Ltd.) is preferred. The resin insulation layer may further contain inorganic particles such as silica particles. In the first embodiment, 4785 GS series made by Sumitomo Bakelite Co., Ltd. is used as the starting material. The thickness of the resin insulation layer is 60 μm, and the thickness of the copper foils is 3 μm.

(2) A laser is irradiated on copper foil 132 formed on the first surface of the resin insulation layer so that openings for interlayer connection conductors (via-conductor openings) 133 are formed to reach copper foil 132 formed on the second surface of the resin insulation layer (FIG. 3(B)). Electroless plated films (131, 131) are formed on the inner walls of the via-conductor openings and on metal foils (132, 132) on both surfaces (FIG. 3(C)). In the first embodiment, an electroless copper plating process is employed.

(3) Electrolytic plated films 135 are formed on electroless plated films on both surfaces. At the same time, via-conductor openings 133 are filled with electrolytic plated film 135 (FIG. 3(D)). In the first embodiment, an electrolytic copper plating process is employed.

(4) Etching resists 139 are formed on electrolytic plated films 135 on both surfaces (FIG. 3(E)).

(5) Electrolytic plated film 135, electroless plated film 131 and metal foil 132 exposed from etching resists 139 are etched away (FIG. 3(F)). Etching resists 139 are removed, and conductive layers (147, 147) are formed on both surfaces of the resin insulation layer. Via conductors 146 are formed at the same time (FIG. 3(G)). The conductive layer on the first surface of the resin insulation layer and the conductive layer on the second surface of the resin insulation layer are connected by interlayer connection conductors (via conductors) 146. Conductive layers include multiple conductive circuits. Via lands are included in conductive circuits. Then, conductive layers are roughened (not shown in the drawings).

(6) Prepreg and a metal foil are laminated in that order on both surfaces of the substrate shown in FIG. 3(G). Then, the prepreg is thermally pressed to form resin insulation layers (130, 130). Metal foils (132, 132) are laminated on those resin insulation layers (FIG. 3(H)). The thickness of the resin insulation layers is 40 μm to 150 μm. The resin insulation layers are formed with resin such as epoxy resin and reinforcing material such as glass cloth. As the material for such glass, T-glass (made by Nitto Boseki Co., Ltd.) is preferred. Moreover, the resin insulation layers may also contain inorganic particles such as silica particles. In the first embodiment, 6785 GS series made by Sumitomo Bakelite Co., Ltd. is used as the prepreg. The thickness of the resin insulation layers is 60 μm, and the thickness of the copper foils is 3 μm.

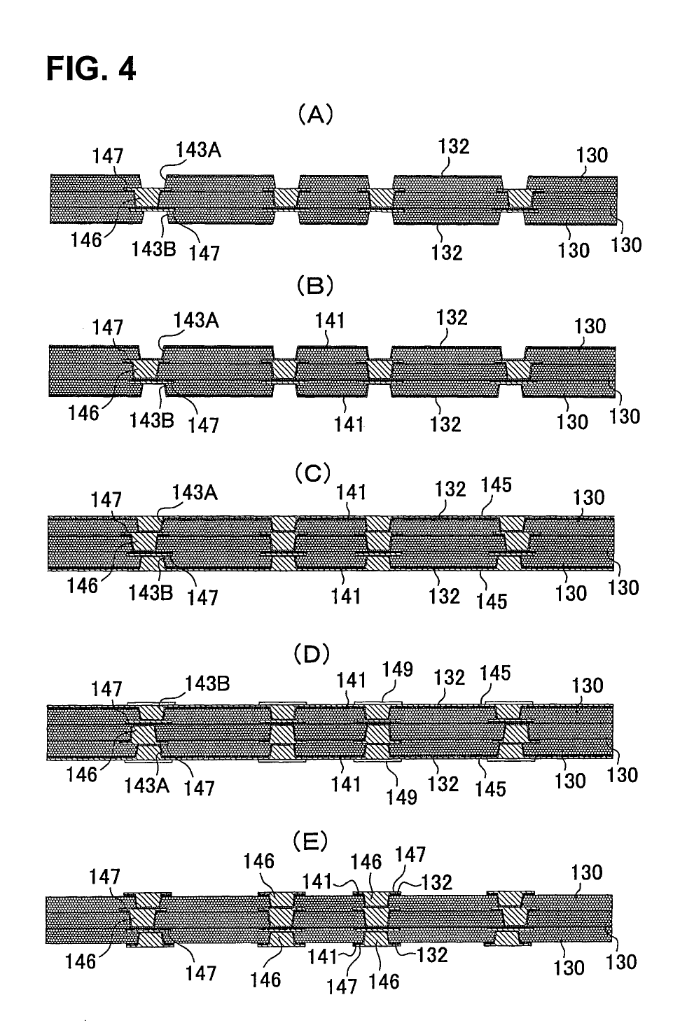

(7) A laser is irradiated on copper foils (132, 132) which are laminated on the first and second surfaces of the resin insulation layer as the starting material with resin insulation layers in between. Openings (143A, 143B) for via conductors are formed in the resin insulation layers laminated on the first and second surfaces of the resin insulation layer as the starting material (FIG. 4(A)). Electroless plated films (141, 141) are formed on copper foils (132, 132) of the substrate shown in FIG. 4(A). Simultaneously, electroless plated films (141, 141) are formed on the inner walls of openings (143A, 143B) (FIG. 4(B)). In the first embodiment, an electroless copper plating process is employed.

(8) Electrolytic plated films (145, 145) are formed on electroless plated films 141. Simultaneously, openings (143A, 143B) are filled with electrolytic plated films (145, 145) (FIG. 4(C)). In the first embodiment, an electrolytic copper plating process is employed.

(9) Etching resists 149 are formed on electrolytic plated films (145, 145) (FIG. 4(D)).

(10) Electrolytic plated film 145, electroless plated film 141 and metal foil 132 exposed from etching resists 149 are etched away. Then, etching resists 149 are removed, and via conductors (146, 146) and conductive layers (147, 147) are formed (FIG. 4(E)). After that, conductive layers (147, 147) are roughened (not shown in the drawings).

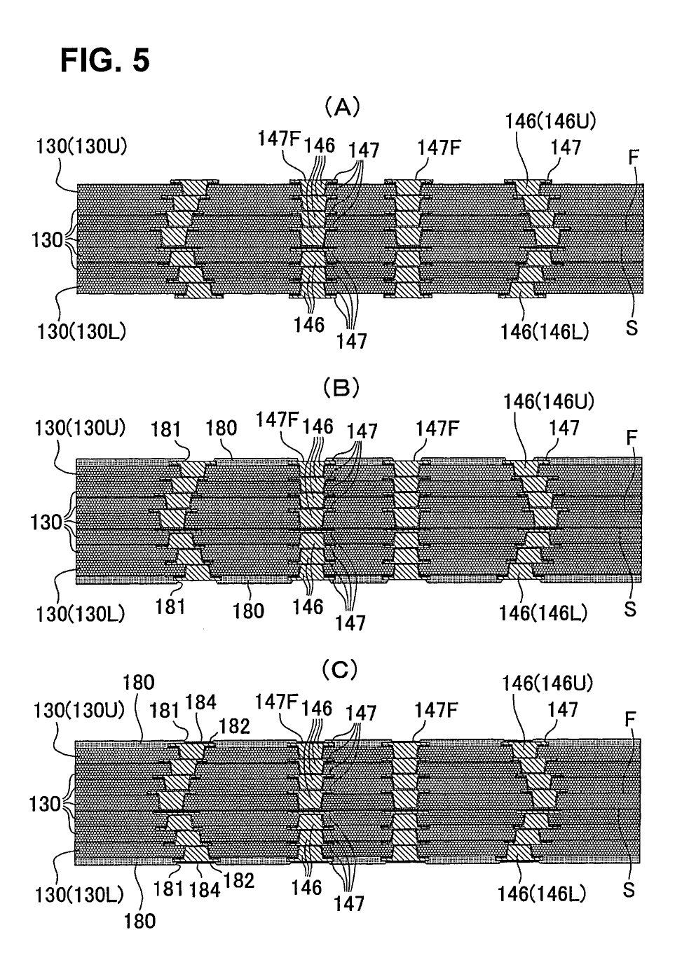

(11) Steps (6)˜(10) above (steps in FIG. 3(H) through FIG. 4(E)) are repeated (FIG. 5(A)). A substrate is completed where resin insulation layers and conductive layers are alternately laminated. The number of resin insulation layers is 7, and the number of conductive layers is 8. Adjacent conductive layers are connected by interlayer connection conductors (via conductors), forming a full stacked-via structure. The thickness of each resin insulation layer is 60 μm, each conductive layer is made up of metal foil, electroless plated film and electrolytic plated film, and the thickness of each conductive layer is 15 μm.

(12) Solder-resist layers 180 having openings 181 are formed on both surfaces of the substrate shown in FIG. 5(A) (FIG. 5(B)). The thickness of the solder-resist layers is 20 μm. External terminals are exposed through the openings in the solder-resist layers.

(13) Nickel-plated layer 182 is formed on external terminals. Gold-plated layer 184 is formed (FIG. 5(C)). Instead of nickel-gold layers, nickel-palladium-gold layers may also be formed. A motherboard is completed.

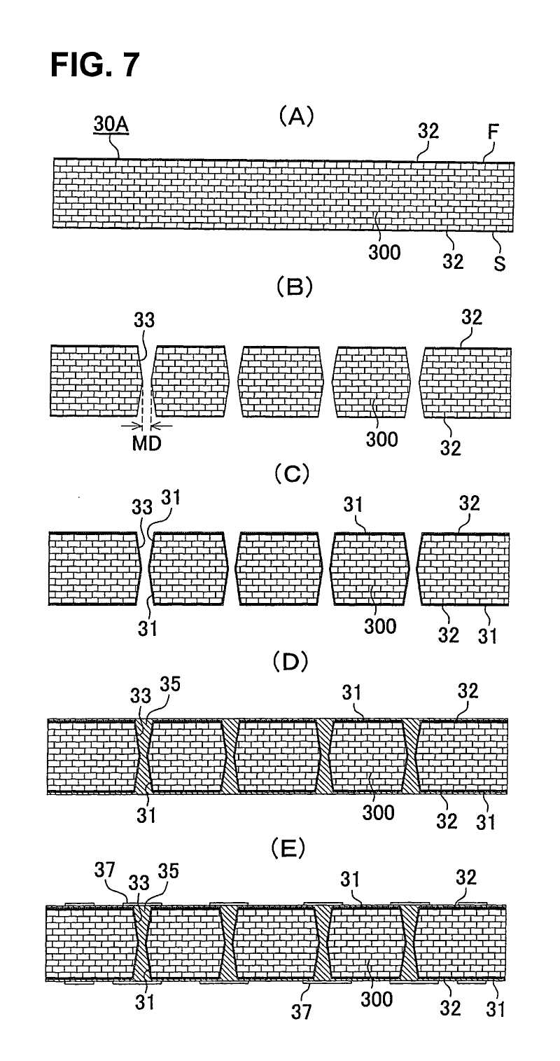

In the following, a method for manufacturing packaging substrate 10 is described with reference to FIG. 7 through FIG. 10.

(1) Substrate (30A) with metal foils is prepared, which is formed with resin substrate 300 and metal foils (32, 32) laminated on both surfaces of resin substrate 300 (FIG. 7(A)). The resin substrate has first surface (F) and second surface (S) opposite the first surface. The thickness of the resin substrate is 60 μm to 150 μm. The resin substrate is formed with resin such as epoxy resin and reinforcing material such as glass cloth. As the material for such glass, T-glass (made by Nitto Boseki Co., Ltd.) is preferred. Moreover, the resin insulation substrate may also contain inorganic particles such as silica particles. In the first embodiment, 4785 GS series made by Sumitomo Bakelite Co., Ltd. is used as the starting material. The thickness of the resin substrate is 60 μm, and the thickness of the copper foils is 3 μm.

(2) Hourglass-shaped penetrating holes 33 for through-hole conductors are formed in resin substrate 300 (FIG. 7(B)). Penetrating holes 33 may be formed by the method described in U.S. Pat. No. 7,786,390. The entire contents of this publication are incorporated herein by reference. Then, electroless plated film 31 is formed on the inner walls of the penetrating holes and on copper foils (32, 32) by performing an electroless plating process (FIG. 7(C)).

(3) By performing an electrolytic plating process, electrolytic plated films (35, 35) are formed on electroless plated films 31. At this time, penetrating holes are filled with electrolytic plated film (FIG. 7(D)). Electroless plated film and electrolytic plated film are both made of copper.

(4) Etching resists 37 are formed on the electrolytic plated films formed on the first and second surfaces of the resin substrate (FIG. 7(E)).

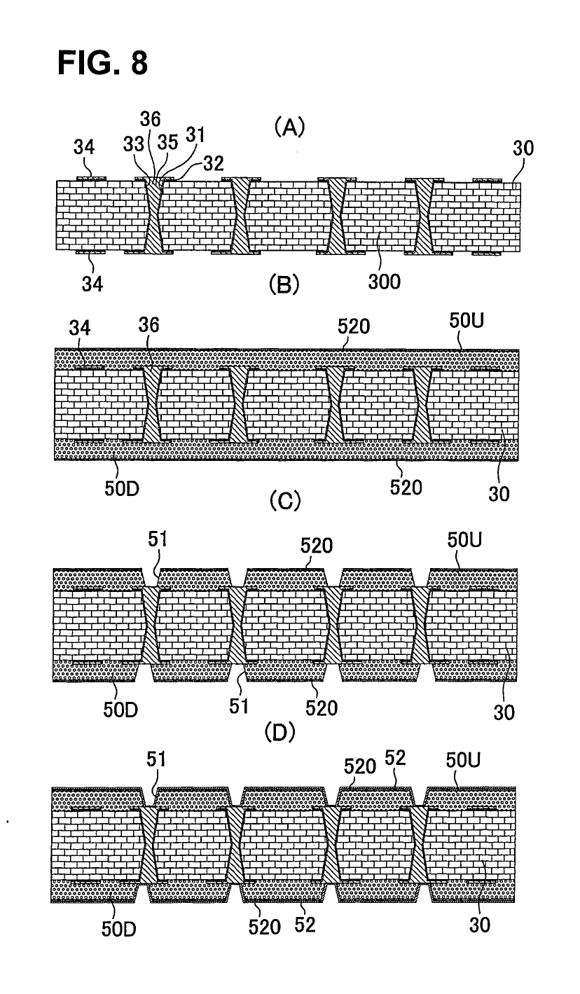

(5) Electrolytic plated film 35, electroless plated film 31 and copper foil 32 exposed from etching resists 37 are etched away. Then, etching resists 37 are removed and through-hole conductors 36 are formed. Simultaneously, conductive layers 34 are formed on the first and second surfaces of the resin substrate. Conductive layers 34 include through-hole lands (FIG. 8(A)). Core substrate 30 is completed. Then, conductive layers 34 are roughened (not shown in the drawings). Plated films are copper-plated films.

(6) Resin film for interlayer resin insulation layers (brand name: ABF-45SH, made by Ajinomoto) and metal foil 520 are placed on both surfaces of core substrate 30. Then, thermal pressing is conducted and interlayer resin insulation layers (50U, 50D) and metal foils (520, 520) are formed on the core substrate (FIG. 8(B)). Copper foil is used for the metal foils, and its thickness is 3 μm. In the present embodiment, interlayer resin insulation layer (50U) is the uppermost interlayer resin insulation layer, and interlayer resin insulation layer (50D) is the lowermost interlayer resin insulation layer. Resin insulation layers used for the motherboard may also be used for those interlayer resin insulation layers.

(7) Next, using a CO2 gas laser, openings 51 for via conductors are formed in interlayer resin insulation layers (50U, 50D) (FIG. 8(C)). The diameter of openings 51 is 40 μm to 70 μm, and the diameter of the openings of the present embodiment is set at 60 μm. Openings 51 are cleansed using an oxidation agent such as permanganate.

(8) Electroless plated film 52 with a thickness of 0.1 μm to 2 μm is formed in openings 51 and on copper foils 520 (FIG. 8(D)). The electroless plated films in the present embodiment are electroless copper-plated films, and their thickness is 0.5 μm.

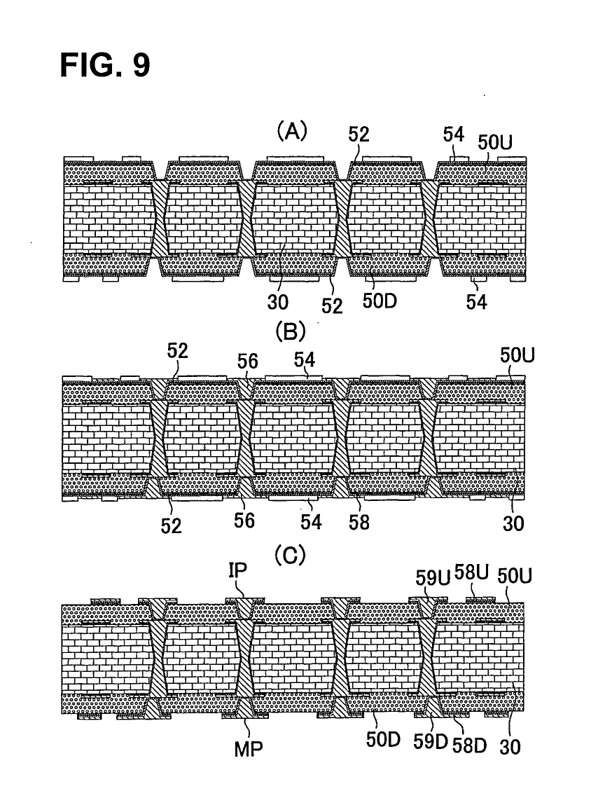

(9) Plating resists 54 with a thickness of 15 μm to 20 μm are formed on electroless plated films 52 (FIG. 9(A)).

(10) Next, electrolytic plated films 56 with a thickness of 6 μm to 18 μm are formed on electroless plated films exposed from plating resists 54 (FIG. 9(B)). The electrolytic plated films in the present embodiment are electrolytic copper-plated films, and their thickness is 12 μm.

(11) Plating resists 54 are removed. Then, electroless plated film 52 and metal foil 520 exposed from the electrolytic plated films are removed. Conductive layers (58U, 58D) and via conductors (59U, 59D) are formed (FIG. 9(C)). Upper and lower buildup layers are completed. Conductive layer (58U) is formed on the uppermost interlayer resin insulation layer, and includes pads (C4 pads) (IP) for mounting a semiconductor element. Conductive layer (58D) includes pads (BGA pads) (MP) for connection with a motherboard. The distance between the centers of adjacent pads (MP) for connection with a motherboard is preferred to be 0.35 mm or less and 0.1 mm or greater. If the distance between pads (MP) for connection with a motherboard is in such a range, heat is transferred efficiently from the packaging substrate to the motherboard.

The upper buildup layers are made up of uppermost interlayer resin insulation layer (50U) formed on the first surface of the core substrate (first surface of the resin substrate), uppermost conductive layer (58U) on the uppermost interlayer resin insulation layer, and uppermost via conductors (59U) which penetrate through the uppermost interlayer resin insulation layer and connect through-hole conductors 36 and uppermost conductive layer (58U). The uppermost conductive layer includes the C4 pads.

The lower buildup layers are made up of lowermost interlayer resin insulation layer (50D) formed on the second surface of the core substrate (second surface of the resin substrate), lowermost conductive layer (58D) on the lowermost interlayer resin insulation layer, and lowermost via conductors (59D) which penetrate through the lowermost interlayer resin insulation layer and connect through-hole conductors 36 and lowermost conductive layer (58D). The lowermost conductive layer includes the BGA pads.

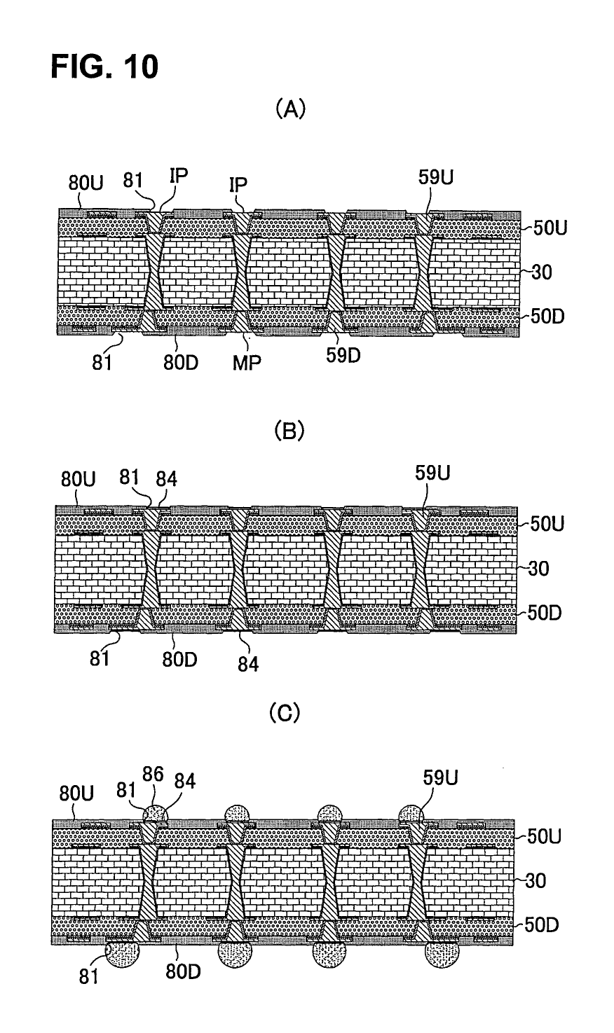

(12) Solder-resist layers (80U, 80D) having openings 81 are formed on the upper and lower buildup layers (FIG. 10(A)). Solder-resist layer (80U) is the upper solder-resist layer, and solder-resist layer (80D) is the lower solder-resist layer. Conductive layers (58U, 58D) and via conductors (59U, 59D) exposed through the openings work as pads (IP, MP). The thickness of the solder-resist layers is approximately 20 μm. Materials for solder-resist layers are obtained from Hitachi Chemical Co., Ltd. or the like.

(13) Next, metal film 84 is formed on pads (IP, MP) (FIG. 10(B)). Tin film or the like is listed for metal film 84.

(14) Solder bumps (86U, 86D) are formed on pads (IP, MP) (FIG. 10(C)).

### Method for Manufacturing Wiring Substrate

The connection of packaging substrate 10 and motherboard 110 is described.

Using alignment marks in the packaging substrate and alignment marks in the motherboard, pads (MP) of the packaging substrate and the external terminals of the motherboard are aligned. Then, the packaging substrate is mounted on the motherboard. After that, a reflow process is conducted to bond the packaging substrate and the motherboard. Wiring substrate 100 is completed. The uppermost resin insulation layer of the motherboard is the resin insulation layer closest to the packaging substrate, and the lowermost resin insulation layer is the resin insulation layer farthest from the packaging substrate.

Resin filler 188 may be filled between motherboard 110 and packaging substrate 10.

Next, semiconductor element 200 is mounted through solder bumps (86U), and underfill 288 is filled between semiconductor element 200 and packaging substrate 10. It is an option for a semiconductor element to be mounted on the packaging substrate, and then for the packaging substrate to be connected to the motherboard. The same materials may be used for resin filler 188 and underfill 288. In doing so, cracking is suppressed from occurring in solder bumps (86U) between the semiconductor element and the packaging substrate as well as in solder bumps (86D) between the packaging substrate and the motherboard.

### Modified Example of the First Embodiment

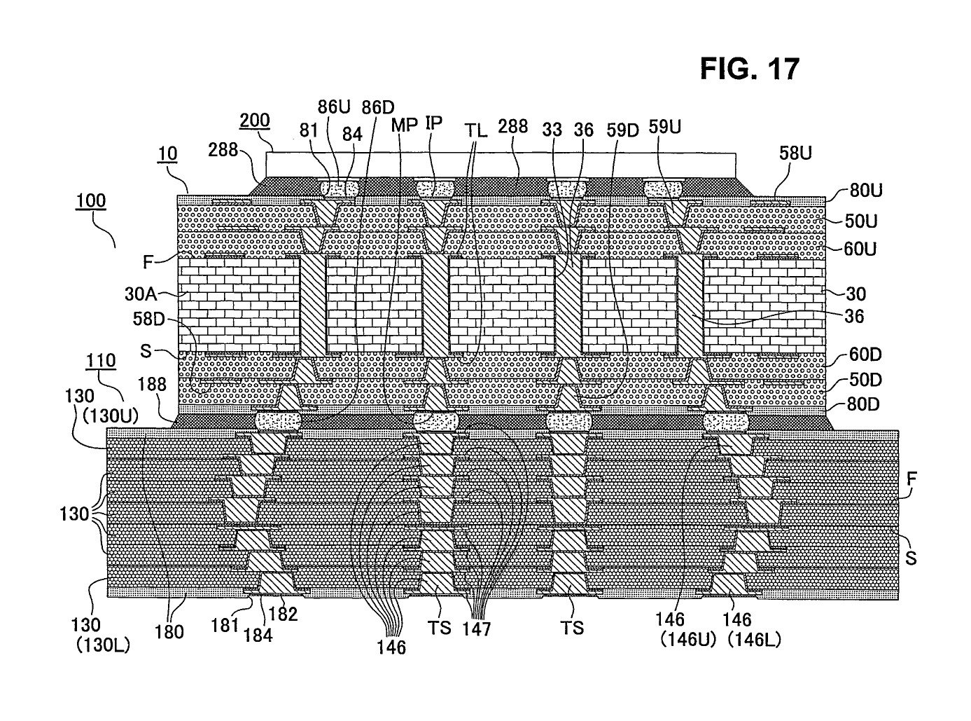

FIG. 17 shows a cross-sectional view of a wiring substrate according to a modified example of the first embodiment. In the first embodiment, the upper and lower buildup layers each have one interlayer resin insulation layer and one conductive layer. By contrast, in a modified example of the first embodiment, the upper and lower buildup layers each have two interlayer resin insulation layers and two conductive layers. Other than that, the number of full stacked-via structures and total stacked structures or the like in a modified example of the first embodiment is the same as in the first embodiment. The same effects as in the first embodiment are achieved in a modified example of the first embodiment.

### Another Modified Example of the First Embodiment

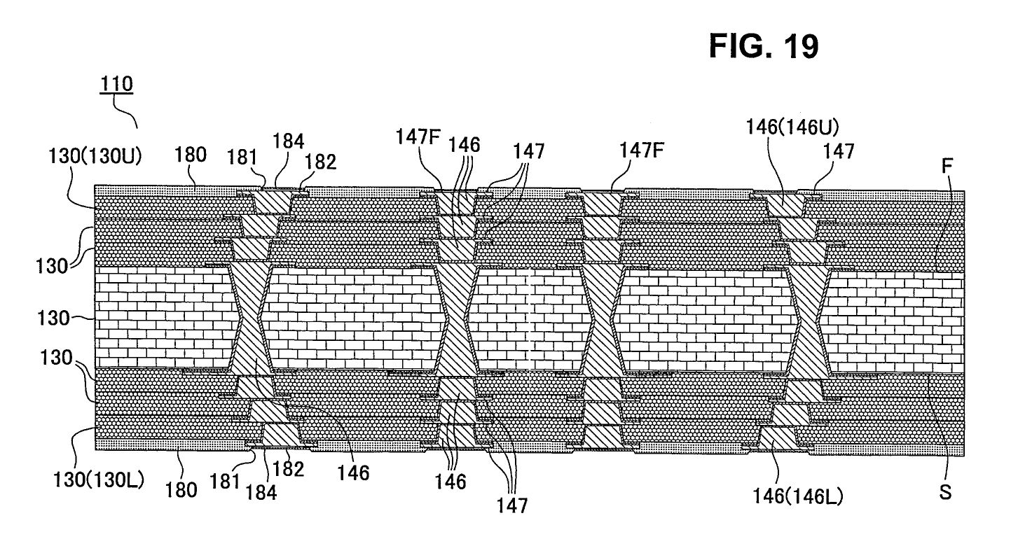

FIG. 19 shows a motherboard according to another modified example of the first embodiment. In such an example, interlayer connection conductors 146 formed in the center in a cross-sectional direction are shaped like an hourglass. The motherboard shown in FIG. 19 is manufactured by the same method used for a packaging substrate in the first embodiment.

### Second Embodiment

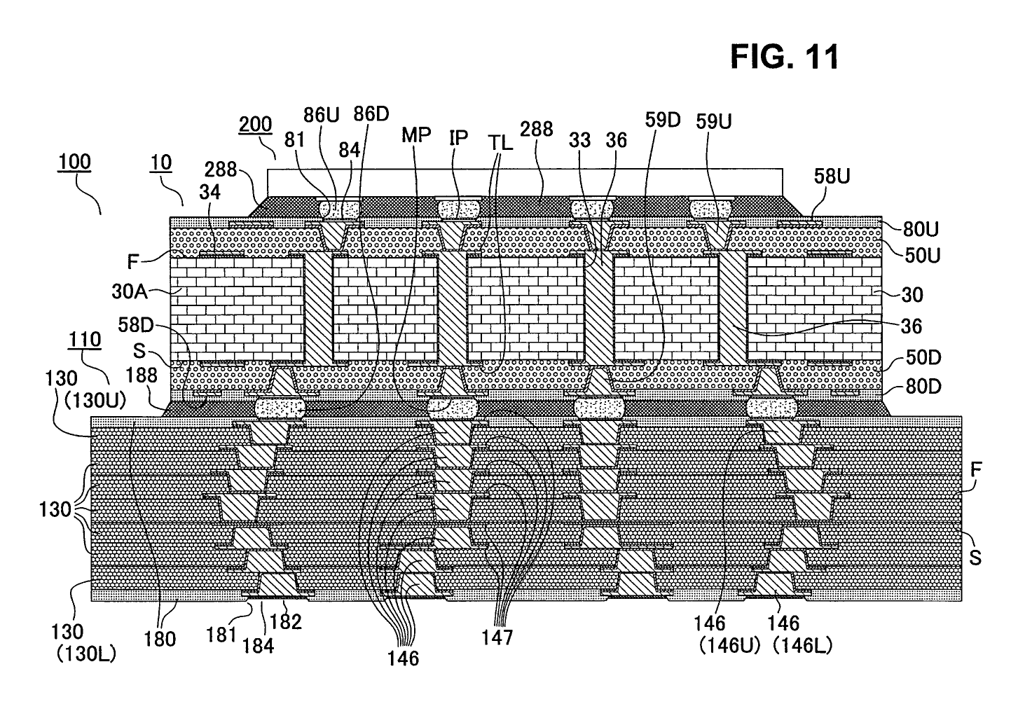

FIG. 11 shows a wiring substrate according to a second embodiment. In the second embodiment, the motherboard has a partial stacked-via structure directly under a full stacked-via structure of the packaging substrate. In a partial stacked-via structure, via conductors from the uppermost resin insulation layer to a via conductor in a predetermined resin insulation layer are laminated along a straight line. Here, when the number of resin insulation layers in motherboard 110 is Mn, and the predetermined resin insulation layer is the Nth layer from the uppermost resin insulation layer, N is preferred to be a whole number greater than Mn/2. Heat diffuses in a horizontal direction of the motherboard. It is more preferable if N is a whole number of 2 Mn/3 or greater. Heat efficiently diffuses in a horizontal direction and a cross-sectional direction of the motherboard. In FIG. 11, Mn is 7, and N is 5. In FIG. 11, two structures in the center are partial stacked-via structures.

In the second embodiment as well, heat generated in semiconductor element 200 is transferred from the packaging substrate to the motherboard by way of a distance close to the minimum distance.

### Third Embodiment

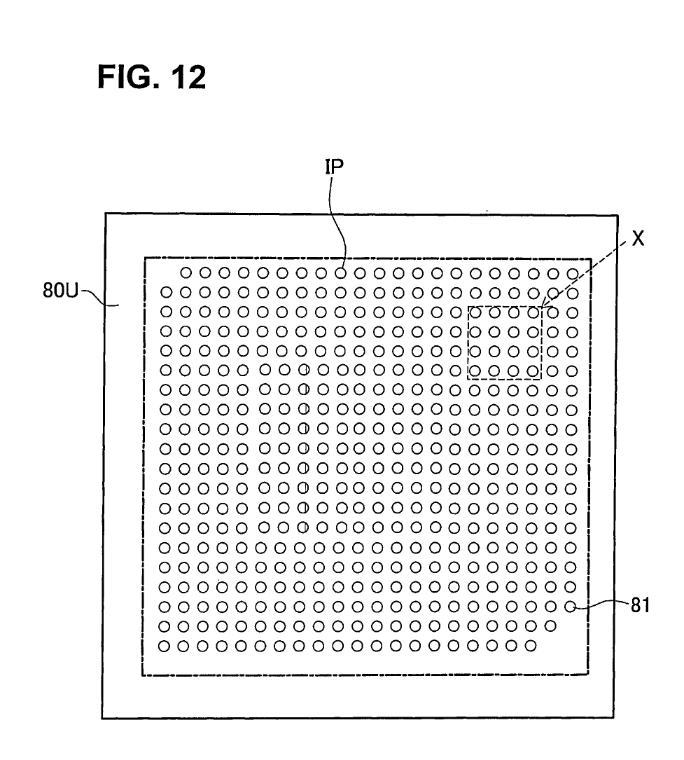

FIG. 12 is a plan view of a packaging substrate, showing upper solder-resist layer (80U) and pads (IP). Pads (IP) in (X) in the drawing are pads (IP) directly under the processor core of the semiconductor element. It is preferred that total stacked-via structures be formed directly under those pads. Heat in the semiconductor element is efficiently cooled. All pads (IP) directly under the processor core are preferred to be part of full stacked-via structures of the packaging substrate. Heat generated in the processor core is efficiently transferred to the motherboard. Moreover, if all pads (IP) directly under the processor core are part of the total stacked-via structures, heat generated in the processor core is transferred all the way to the lower side of the motherboard.

In the first embodiment, in a modified example of the first embodiment, in another modified example of the first embodiment, and in the second embodiment and the third embodiment, since a semiconductor element is efficiently cooled, the semiconductor element is unlikely to malfunction, allowing it to operate for a long duration at maximum frequency.

A wiring substrate according to an embodiment of the present invention is formed with a motherboard, a packaging substrate, and a bonding member to connect the motherboard and the packaging substrate. The packaging substrate is formed with the following: a core substrate made up of a resin substrate having a first surface and a second surface opposite the first surface and of a through-hole conductor penetrating through the resin substrate; an uppermost interlayer resin insulation layer formed on the first surface of the resin substrate and on the through-hole conductor; a pad formed on the uppermost interlayer resin insulation layer for mounting a semiconductor element; an uppermost via conductor penetrating through the uppermost interlayer resin insulation layer and connecting the through-hole conductor and the pad for mounting a semiconductor element; a lowermost interlayer resin insulation layer formed on the second surface of the resin substrate and on the through-hole conductor; a pad formed on the lowermost interlayer resin insulation layer for connection with a motherboard; and a lowermost via conductor penetrating through the lowermost interlayer resin insulation layer and connecting the through-hole conductor and the pad for connection with a motherboard. The motherboard is formed with the following: multiple resin insulation layers and multiple conductive layers which are alternately laminated; and interlayer connection conductors penetrating through their respective resin insulation layers and connecting different conductive layers. In such a wiring substrate, pads for connection with a motherboard include multiple first pads, and the lowermost via conductor connected to a first pad, the through-hole conductor, the uppermost via conductor, the bonding member, and the interlayer connection conductor formed in each resin insulation layer of the motherboard are laminated along a straight line.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring substrate, comprising:
a motherboard comprising a plurality of resin insulation layers, a plurality of conductive layers, and a plurality of interlayer connection conductors connecting the conductive layers through the resin insulation layers;
a packaging substrate mounted to the motherboard, the packaging substrate comprising a core substrate including a resin substrate, a plurality of through-hole conductors penetrating through the resin substrate, an uppermost interlayer resin insulation layer formed on a first surface of the resin substrate, a plurality of pads formed on the first interlayer resin insulation layer and positioned to mount a semiconductor device, a plurality of uppermost via conductors connecting the through-hole conductors and the pads for the semiconductor device through the uppermost interlayer resin insulation layer, a lowermost interlayer resin insulation layer formed on a second surface of the resin substrate, a plurality of pads formed on the lowermost interlayer resin insulation layer and positioned to connect a motherboard, and a plurality of lowermost via conductors connecting the through-hole conductors and the pads for the motherboard through the lowermost interlayer resin insulation layer; and
a plurality of bonding structures interposed between the motherboard and the packaging substrate and connecting the pads for the motherboard in the packaging substrate and an outermost conductive layer of the conductive layers in the motherboard facing the packaging substrate,
wherein the plurality of pads for the motherboard, the plurality of lowermost via conductors, the plurality of through-hole conductors, the plurality of uppermost via conductors, the plurality of bonding structures, and the plurality of interlayer connection conductors include a pad, a lowermost via conductor, a through-hole conductor, a bonding structure and a stacked interlayer connection conductor structure which are positioned to align in a straight line.

2. The wiring board according to claim 1, wherein the pad aligned in the straight line with the lowermost via conductor, the through-hole conductor, and the stacked interlayer connection conductors forms a ground line.

3. The wiring board according to claim 1, wherein the pads for the motherboard, the lowermost via conductors, the through-hole conductors, the uppermost via conductors, the bonding structures and the interlayer connection conductors include a group of the pads, a group of the lowermost via conductors, a group of the through-hole conductors, a group of bonding structures and a plurality of stacked interlayer connection conductor structures which are positioned to align in straight lines and form ground lines, the plurality of pads for the motherboards includes a plurality of pads forming ground lines, and the group of pads aligned in the straight lines is 1/5 to 1/2 of an entire number of the plurality of pads forming the ground lines for the motherboard.

4. The wiring board according to claim 1, wherein the pads for the motherboard, the lowermost via conductors, the through-hole conductors, the uppermost via conductors, the bonding structures and the interlayer connection conductors include a group of the pads, a group of the lowermost via conductors, a group of the through-hole conductors, a group of bonding structures and a plurality of stacked interlayer connection conductor structures which are positioned to align in straight lines, and the group of pads aligned in the straight lines is 1/5 to 1/2 of an entire number of the plurality of pads for the motherboard.

5. The wiring board according to claim 1, wherein the uppermost interlayer resin insulation layer is formed directly on the core substrate, and the lowermost interlayer resin insulation layer is formed directly on the core substrate.

6. The wiring board according to claim 1, wherein the packaging substrate includes an upper interlayer resin insulation layer formed between the uppermost interlayer resin insulation layer and the core substrate, an upper via conductor penetrating through the upper interlayer resin insulation layer, a lower interlayer resin insulation layer formed between the lowermost interlayer resin insulation layer and the core substrate, and a lower via conductor penetrating through the lower interlayer resin insulation layer, and the upper and lower via conductors are aligned in the straight line.

7. The wiring board according to claim 6, wherein the upper interlayer resin insulation layer is formed directly on the core substrate, the lower interlayer resin insulation layer is formed directly on the core substrate, the uppermost interlayer resin insulation layer is formed directly on the upper interlayer resin insulation layer, and the lowermost interlayer resin insulation layer is formed directly on the lower interlayer resin insulation layer.

8. The wiring board according to claim 1, wherein the pads for the motherboard has a distance between the pads which is in a range of 0.35 mm or less.

9. The wiring board according to claim 1, wherein the plurality of pads for the motherboard, the plurality of lowermost via conductors, the plurality of through-hole conductors, the plurality of uppermost via conductors, the plurality of bonding structures, and the plurality of interlayer connection conductors include a group of the pads, a group of the lowermost via conductors, a group of the through-hole conductors, a group of bonding structures and a group of stacked interlayer connection conductor structures which are positioned to align in straight lines.

10. The wiring board according to claim 1, wherein the plurality of pads for the motherboard, the plurality of lowermost via conductors, the plurality of through-hole conductors, the plurality of uppermost via conductors, the plurality of bonding structures, and the plurality of interlayer connection conductors include a group of the pads, a group of the lowermost via conductors, a group of the through-hole conductors, a group of bonding structures and a group of stacked interlayer connection conductor structures which are positioned to align in a straight line, and the group of the pads, the group of the lowermost via conductors, the group of the through-hole conductors, and the group of stacked interlayer connection conductor structures aligned in straight lines form a plurality of ground lines, respectively.

11. The wiring board according to claim 1, further comprising a resin filler structure interposed between the packaging substrate and the motherboard and comprising a resin filler filling a space between the packaging substrate and the motherboard.

12. The wiring board according to claim 1, wherein the plurality of bonding structures are a plurality of solder bumps.

13. The wiring board according to claim 1, wherein each of the through-hole conductors in the packaging substrate has an hour-glass shape.

14. The wiring board according to claim 1, wherein the stacked interlayer connection conductor structure is a full stacked-via structure formed through the plurality of resin insulation layers.

15. The wiring board according to claim 1, wherein the uppermost interlayer resin insulation layer is formed directly on the core substrate, the lowermost interlayer resin insulation layer is formed directly on the core substrate, and the pads for the motherboard, the lowermost via conductors, the through-hole conductors, the uppermost via conductors, the bonding structures and the interlayer connection conductors include a group of the pads, a group of the lowermost via conductors, a group of the through-hole conductors, a group of bonding structures and a plurality of stacked interlayer connection conductor structures which are positioned to align in straight lines.

16. The wiring board according to claim 1, further comprising:
a semiconductor device mounted to the packaging substrate; and
a plurality of bonding structures bonding the semiconductor to the plurality of pads positioned to mount a semiconductor device.

17. The wiring board according to claim 1, further comprising:
a semiconductor device mounted to the packaging substrate;
a plurality of bonding structures bonding the semiconductor to the plurality of pads positioned to mount a semiconductor device; and
an underfill interposed between the semiconductor device and the packaging substrate and comprising an underfill resin filling a space between the semiconductor device and the packaging substrate.

18. The wiring board according to claim 1, wherein the pads for the motherboard has a distance between the pads which is in a range of 0.35 mm or less, and the pads for the motherboard, the lowermost via conductors, the through-hole conductors, the uppermost via conductors, the bonding structures and the interlayer connection conductors include a group of the pads, a group of the lowermost via conductors, a group of the through-hole conductors, a group of bonding structures and a plurality of stacked interlayer connection conductor structures which are positioned to align in straight lines.

19. The wiring board according to claim 1, wherein the plurality of interlayer connection conductors is a plurality of via conductors connecting the conductive layers through the resin insulation layers.

20. The wiring board according to claim 1, wherein each of the through-hole conductors in the packaging substrate has an hour-glass shape, and the stacked interlayer connection conductor structure is a full stacked-via structure formed through the plurality of resin insulation layers.
